(19) United States
(12) Patent Application Publication
(10) Pub. No.: US 2020/0136003 A1
(43) Pub. Date: Apr. 30, 2020

(54) Thermoelectric Materials and Devices

(71) Applicant: Florida State University Research Foundation, Inc., Tallahassee, FL (US)

(72) Inventors: Kaya Wei, Tallahassee, FL (US); Theo Siegrist, Tallahassee, FL (US); Ryan Baumbach, Tallahassee, FL (US)

(21) Appl. No.: 16/700,050

(22) Filed: Dec. 2, 2019

Related U.S. Application Data
(63) Continuation-in-part of application No. 16/384,256, filed on Apr. 15, 2019.
(60) Provisional application No. 62/680,277, filed on Jun. 4, 2018.

(51) Int. Cl. H01L 35/18; H01L 35/34; H01L 35/04

(52) U.S. Cl. CPC H01L 35/18; H01L 35/04; H01L 35/34

(57) ABSTRACT

1-2-20 semiconductor compounds have advantageous thermoelectric properties. An exemplary apparatus includes a thermoelectric device including a first thermoelectric material having the formula RₓT_{y}M_{z} where R is at least one rare earth metal, Ba, or Bi and 0≤x≤1; T is at least one transition metal and 0<y≤2; and M is at least one member of the group Al, Zn, Ga, Cd, and In and 0<z≤20.

### CROSS-REFERENCE TO RELATED APPLICATION

This is continuation-in-part of application Ser. No. 16/384,256, filed Apr. 15, 2019, which claims the benefit of priority to provisional Application No. 62/680,277, filed Jun. 4, 2018. The entire contents of these prior applications are incorporated by reference.

### STATEMENT REGARDING FEDERALLY SPONSORED RESEARCH AND DEVELOPMENT

This invention was made with government support under contract DE-SC0016568 awarded by the U.S. Department of Energy and contract NSF 1606952 awarded by the National Science Foundation. The government has certain rights in the invention.

### FIELD

This relates to the field of materials and, more particularly, to materials with improved thermoelectric properties.

### BACKGROUND

Thermoelectric devices make it possible for direct energy conversion between heat and electricity (and vice versa). In order to achieve a high energy conversion efficiency, materials with a high thermoelectric figure of merit (ZT=S²σT/κ, where S is the Seebeck coefficient, σ is the electrical conductivity, T is the absolute temperature, and κ is the thermal conductivity) are in great demand.

The standard approach to making thermoelectric materials is to optimize the charge carrier transport while minimizing thermal conductivity. Obtaining the proper balance between charge transport and heat transport is extremely difficult because electrical transport and the thermal transport are fundamentally associated with each other. For example, improving the electrical properties in order to increase ZT is limited since electrons also carry heat, among other reasons, resulting in higher κ with a higher σ.

### BRIEF SUMMARY

It has been discovered that 1-2-20 semiconductor compounds have advantageous thermoelectric properties and may be used in a thermoelectric apparatus for many applications.

An example of the thermoelectric apparatus comprises a thermoelectric device including a first thermoelectric material having the formula RₓT_{y}M_{z} where R is at least one rare earth metal, Ba, or Bi and 0≤x≤1; T is at least one transition metal and 0≤y≤2; and M is at least one member of the group Al, Zn, Ga, Cd, and In and 0<z≤20.

An example of a method of making a thermoelectric device comprises connecting electronic circuitry to a thermoelectric device including a first thermoelectric material having the formula RₓT_{y}M_{z} where R is at least one rare earth metal, Ba, or Bi and 0≤x≤1; T is at least one transition metal and 0<y≤2; and M is at least one member of the group Al, Zn, Ga, Cd, and In and 0<z≤20.

The apparatus and method may include any of the following additional features.

The device may be selected from a thermoelectric refrigerator, a thermoelectric heater, and a thermoelectric electrical generator.

The first thermoelectric material may be an n-type semiconductor and the device further includes a second thermoelectric material that is a p-type semiconductor.

In a particular example, R is selected from Bi, Ba, Y, La, Ce, Pr, Nd, Pm, Sm, Eu, Gd, Tb, Dy, Ho, Er, Tm, Yb, Lu, Th, U, Np, and Pu.

In a particular example, R is Yb and Ce.

In a particular example, T is at least one member of the group Ag, Ti, V, Cr, Mn, Fe, Co, Ni, Cu, Mo, Ru, Rh, Pd, W, Os, Ir, and Pt.

In a particular example, T includes at least one member of the group Co, Rh, and Ir.

In a particular example, M includes Zn.

In a particular example, R is Yb and Ce; T includes at least one of Co, Rh, and Ir; and M includes Zn.

The first thermoelectric material may, in some examples, be selected from Yb_{0.75}Ce_{0.25}Co₂Zn₂₀, Yb_{0.75}Ce_{0.25}Rh₂Zn₂₀, Yb_{0.75}Ce_{0.25}Ir₂Zn₂₀.

The first thermoelectric material is in electrical contact with electronic circuitry in the thermoelectric device.

### BRIEF DESCRIPTION OF THE DRAWINGS

FIG. 1 is a schematic of a thermoelectric heating and refrigeration unit module.

FIG. 2 is a schematic of a thermoelectric electrical generation unit.

FIG. 3 is a set of images showing structural features where (A) is a photograph of single crystals of YbCo₂Zn₂₀ synthesized by flux growth method, (B) is a [111] directional view of the unit cell of YbT₂Zn₂₀, suggesting a Kagome lattice formed by Yb and T atoms, (C) is a depiction of the polyhedron representation of the unit cell with the T cage as the center, (D) is a depiction of the polyhedron representation of the unit cell with Yb as the center, (E) is a depiction of the polyhedron representation of the unit cell with the T cage as the center, and (F) is a depiction of the Frank-Kasper polyhedron formed by Yb and Zn atoms.

FIG. 4 is a table of the diameters of the Frank-Kasper polyhedrons in the lattice.

FIG. 5 is a graph of the temperature dependent Seebeck coefficient of YbCo₂Zn₂₀ (circle), YbRh₂Zn₂₀ (up triangle), and YbIr₂Zn₂₀ (down triangle). The dashed line indicates S=0 and the solid line is a extrapolation of the S of YbIr2Zn20 at higher temperature.

FIG. 6 is a graph of the temperature dependent electrical resistivity of YbCo₂Zn₂₀ (circle), YbRh₂Zn₂₀ (up triangle), and YbIr₂Zn₂₀ (down triangle). The solid lines are fits of the form ρ=ρ₀ exp(Eₐ/k_{B}T) to the highest temperate data.

FIG. 7 is a set of graphs of the temperature dependent heat capacity of (A) YbCo₂Zn₂₀, (B) YbRh₂Zn₂₀, and (C) YbIr₂Zn₂₀. The inset shows Cp/T versus T² data at low temperatures.

FIG. 8 is a set of graphs of the temperature dependent thermal conductivity (A) and lattice thermal conductivity (B) for YbCo₂Zn₂₀ (circle), YbRh₂Zn₂₀ (up triangle), and YbIr₂Zn₂₀ (down triangle). The solid lines are fits based on Eqs. (1) and (2).

FIG. 9 is a table of the fitting parameters of the κ_{L} using the Debye model as described in the text.

FIG. 10 is a set of graphs of the temperature dependent (A) PF and (B) ZT of YbCo₂Zn₂₀ (circle), YbRh₂Zn₂₀ (up triangle), and YbIr₂Zn₂₀ (down triangle). The insets in (a) and (b) are the PF and the ZT values of several well-known thermoelectric materials at 35 K.

FIG. 11 is a set of graphs comparing the properties of (Yb_{0.75}Ce_{0.25})Co₂Zn₂₀ (circles) and YbCo₂Zn₂₀ (stars) where: (A) represents the temperature dependent Seebeck coefficient; (B) represents the temperature dependent thermal conductivity; (C) represents the temperature dependent resistivity; and (D) represents the temperature dependent ZT. After putting multiple atoms on the R site of RCo₂Zn₂₀, the maximum ZT value has been increased by an order of magnitude.

### DETAILED DESCRIPTION OF EXAMPLE EMBODIMENTS

This disclosure describes example aspects and embodiments, but not all possible aspects embodiments of the materials, devices, and methods. Where a particular feature is disclosed in the context of a particular aspect or embodiment, that feature can also be used, to the extent possible, in combination with and/or in the context of other examples and embodiments. The materials, devices, and methods may be embodied in many different forms and should not be construed as limited to only the embodiments and examples described here.

Described herein is a new strategy of achieving high power factor or “PF” (PF=S²σ) and low K using the hybridization effect of f-electrons in 1-2-20 heavy-fermion compounds. This disclosure shows that the 1-2-20 family of compounds are thermoelectric materials that are especially advantageous for low temperature applications, but may be used at higher temperatures as well.

A first example of the thermoelectric material has the formula RT₂M₂₀ where R is a rare earth element, Ba, or Bi; T is at least one transition metal; and M is at least one member of the group Al, Zn, Ga, Cd, and In.

A second example of the thermoelectric material has the formula RₓT_{y}M_{z} where R is at least one rare earth metal, Ba, or Bi and 0≤x≤1; T is at least one transition metal and 0<y≤2; and M is at least one member of the group Al, Zn, Ga, Cd, and In and 0<z≤20.

In certain examples of the material, R is selected from at least one of Bi, Ba, Y, La, Ce, Pr, Nd, Pm, Sm, Eu, Gd, Tb, Dy, Ho, Er, Tm, Yb, Lu, Th, U, Np, and Pu. In examples where R is composed of more than one of these elements, x represents to total of the R elements. For example, if R=R′_{x′}R″_{x″}R′″_{x′″}, where R′, R″, and R′″ are three different elements, x=x′+x″+x′″. In other examples, R may be composed of any number of different elements and x=x′+x″+ . . . xⁿ where n represents the number of elements. If R is composed of 2 elements, n=2. If R is composed of 3 elements, n=3. If R is composed of 4 elements, n=4.

In certain examples of the material, T is at least one member of the group Ag, Ti, V, Cr, Mn, Fe, Co, Ni, Cu, Mo, Ru, Rh, Pd, W, Os, Ir, and Pt. In examples where T is composed of more than one of these elements, y represents to total of the T elements. For example, if T=T′_{y′}T″_{y″}T′″_{y′″}, where T′, T″, and T″ are three different elements, y=y′+y″+y′″. In other examples, T may be composed of any number of different elements and y=y′+y″+ . . . yⁿ where n represents the number of elements. If T is composed of 2 elements, n=2. If T is composed of 3 elements, n=3. If T is composed of 4 elements, n=4.

In examples where M is composed of more than one element, z represents to total of the M elements. For example, if M=M′_{z′}M″_{z″}M′″_{z′″}, where M′, M″, and M″ are three different elements, z=z′+z″+z′″. In other examples, M may be composed of any number of different elements and z=z′+z″+ . . . zⁿ where n represents the number of elements. If M is composed of 2 elements, n=2. If M is composed of 3 elements, n=3. If M is composed of 4 elements, n=4.

In certain examples of the thermoelectric material, it is not necessary for x, y, or z, respectively, to be an integer. For example, x, y, and/or z may be a fraction such that a formula such as R_{0.5}T_{1.6}M_{18.5} is permitted.

The thermoelectric material may crystallize in a Kagome lattice with R at the center of a cage-like structure including a z atom cluster of M. Because R is not well-bonded to the cage-like structure, R, exhibits rattling behavior, which creates a soft lattice mode that affect phonon and, therefore, heat transport through the material.

If x<1, the vacancies at R site of the lattice may introduce mass fluctuation phonon scattering which may reduce the lattice thermal conductivity to improve the ZT value. If T<2 or M<20, the vacancies on T and M sites will allow tuning of the electronic properties and will introduce point defect phonon scatterings, which may be beneficial for increasing ZT values.

The properties of the thermoelectric material may be tuned by selecting different elements and combinations thereof for use in the formula. Any combination of the elements discussed above may be employed. By using different combinations of elements, the thermal and electric properties of the material can be changed or tuned as desired. For example, R, T, and M may include the same respective element for each unit or different elements for each unit.

The thermoelectric material may also be doped with one or more impurities to change its semiconductor properties in a similar manner as conventional semiconductors such as silicon and germanium are doped.

The thermoelectric material may be prepared as an n-type or p-type semiconductor, depending on the elements and/or dopants selected for use. By way of example, replacing Yb with Ce in the formula may change the material from an n-type to a p-type semiconductor.

The thermoelectric material may be synthesized using, for example, a molten flux growth method. In an example of such a method pieces of the selected R, T, and M elements are heated in a vacuum sealed container to a temperature sufficient to form a molten flux. Upon cooling the molten flux, crystals of the desired material form, which can be separated from any remaining flux by a mechanical separation technique such as centrifugation.

In this example method the R, T, and M elements are combined in a stoichiometric ratio with an excess of M. For example, an R:T:M ratio of 1:2:60 produces the desired material. It should be understood, however, the scope of possible examples of the synthesis method may extend beyond this example.

The temperature to which the elements are heated to form a molten flux can vary, depending on the elements selected. An example of a typical heating temperature is about 1000° C. to about 1100° C. Heating may be conducted at a controlled rate of from about 40 to about 60° C. per hour. The heating temperature may be maintained for a specified time such as 24 hours, for example. The cooling rate may be controlled so that the molten flux cools by about 2 to about 6° C. per hour to an endpoint temperature. At the endpoint temperature, crystals of the material are removed. The endpoint temperature may be, for example, about 600° C. to about 800° C.

The thermoelectric material may also be prepared by other methods. In a direct synthesis method, the elements are mixed in the desired end ratio then heated in a furnace under an inert atmosphere. In an arc melting method, the elements in the desired ratio are arc melted together then heated in a furnace under an inert atmosphere. An inert atmosphere may be achieved using a vacuum or inert gas.

The thermoelectric material may be used as a component of a thermoelectric device by attaching the desired electrical circuitry to the material that forms the desired type of thermoelectric device.

Thermoelectric devices allow for the direct conversion of heat into electricity as well as solid-state heating and refrigeration. For example, thermoelectric generators are solid-state energy converters that combine thermal and electrical properties to convert heat into electricity or electrical power into refrigeration or heating. Thermoelectric devices have the added benefit that they may, if desired, include no moving parts and can be miniaturized. This means that they have long lifetimes and can be deployed in environments where traditional devices work poorly. These features are particularly important if (1) a device cannot be regularly serviced (e.g., on a satellite) and (2) if localized cooling is needed (e.g., on a high-performance computer chip).

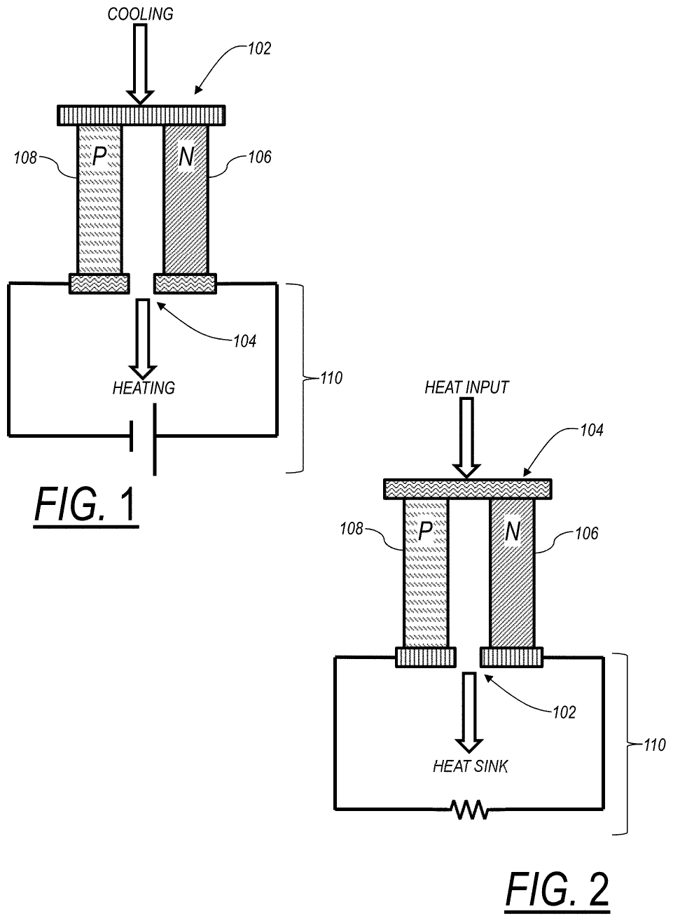

FIG. 1 is a schematic of an example of a thermoelectric heater or refrigeration device. The device includes a cooled surface 102 that absorbs heat and a heated surface 104 that releases heat. An n-type semiconductor leg 106 and a p-type semiconductor leg 108 are positioned between the cooled surface 102 and heated surface 104. The legs 106, 108 are electrically in series and thermally in parallel so that sufficient heat transport is carried through the legs by the charge carriers. Electrical circuitry 110 connects the legs 106,108. An electric current passing through the legs 106, 108 results in the transfer of thermal energy via the charge carriers, thus acting as a refrigerator or a heater.

FIG. 2 is a schematic of a thermoelectric generator using the same reference numbers as in FIG. 1. Imposing a thermal gradient across the legs 106, 108 generates a thermoelectric voltage. Providing a current through the resistive load produces electrical power.

The cooling/heating power and the electrical power generated by these devices can be tuned for the situation in which the device is to be used. The device may include many of the N/P modules working in concert to achieve the desired power.

The properties of the devices can also be tuned by varying the compositions of both the n and p-type materials, which can be used in a homojunction-type design in constructing thermoelectric modules.

The n- and p-type semiconductors may all be a thermoelectric material compounds or some of them may be composed of a different semiconductor material. For example, the thermoelectric material compounds can be used as one of the two legs 106, 108 while the other leg is from another thermoelectric material, forming heterojunction-type connections. For instance, YbIr₂Zn₂₀, an n-type semiconductor at low temperatures can be paired with the p-type semiconductor Bi₂Te₃ as the two legs 106, 108 of an exemplary thermoelectric module.

The thermoelectric figure of merit properties of the thermoelectric material may be adjusted. Variables that may affect the figure of merit are grain size and composition. A magnetic field may also be used to affect the figure of merit.

The thermoelectric material has many technical applications. Certain possible examples, but not all possible examples, of applications of the thermoelectric material are now described.

The thermoelectric material may be particularly useful in low temperature refrigeration devices. Thermoelectric refrigeration devices are advantageous because they are typically compact, lightweight, have no or few moving parts, have low noise, and are environmentally friendly since no gaseous refrigerants are required in most cases. In addition, thermoelectric devices can be made into very small scales to fulfill different requirements regarding small size devices.

The thermoelectric device may be used in cooling sensitive detectors, such as radiation and/or electrical detectors. The device can be used to reduce the noise in high sensitivity receivers and improve the signal/noise ratio of the detectors. The thermoelectric device may be used in low temperature cooling units or cryostats. Conventional liquid nitrogen cryostats can provide a cooling temperature down to about 70 K. The thermoelectric device is capable of operating at about 70 K and may provide additional cooling to lower the temperature of the system below 70 K without introducing helium, which has become expensive and difficult to obtain.

The thermoelectric device may be used to supplement using helium for more economically efficient refrigeration at low temperatures below 70 K. Low temperature refrigeration at temperatures typically below 70 K down to about 2 K, but sometimes down to a few mK, usually requires strict conditions and is extremely expensive. The cost of liquid helium is high, which limits the capability of enabling low temperature research and development. Using the thermoelectric device as a supplement to liquid helium will reduce the overall cost of low temperature research and development. The thermoelectric device may be used for higher efficiency spot cooling in electronic devices. Cooling high power density electronic devices can be achieved by lowering and maintaining the lower temperature side of the cooling system. In this way, more heat can be transferred away, allowing a higher power level/performance of the electronic devices.

The thermoelectric device may also be particularly useful for electrical power generation. Some, but not all possible examples of power generation applications are now discussed.

The thermoelectric device may be used for deep space power generation. Considerable effort by NASA and other agencies has established radioisotope thermoelectric generator (RTG) as the power source for deep space missions and therefore an integral component of space exploration. RTGs convert heat, generated by the radioactive decay of plutonium 239, into electricity and supply power to the Cassini and Discovery deep space probes. Thermoelectric power generation is uniquely valuable in deep space exploration since there are no other solutions for deep space power generation.

The thermoelectric device may be used for small-scale remote power generation. In addition, as electronic devices for spacecraft have become miniaturized and power needs have decreased, miniature power sources have become more important. A miniature or micro-device such as a sensor, an actuator, or electronic components require milliwatts of power at a few to several tens of volts. As devices shrink power needs also shrink and the development of power conversion devices in which milliwatts are provided with high specific power become important. Thermoelectric power generators such as the thermoelectric device fit this need. Shrinking the size of the thermoelectric elements makes it possible to operate at much lower power with a higher heat flux, leading to better performance.

The thermoelectric device may be used as a power supply for a cardiac pacemaker. Conventional pacemakers suffer from the drawback that their batteries must be changed. The thermoelectric device can provide an alternative way to power the pacemaker without the need to change batteries.

The thermoelectric device may be used for low temperature power generation. The thermoelectric material can produce power at low temperatures, with one leg of the thermoelectric power generator at temperatures below 77 K, a condition found in deep space.

The thermoelectric device may be constructed using at least one RₓT_{y}M_{z} compound by conventional semiconductor device production methods. The device may accordingly include metals, ceramics, solders, conductive pastes, and/or electrically insulating features, depending on the device being made.

An example of a method of making a thermoelectric device includes connecting electronic circuitry to the thermoelectric device including the thermoelectric material having the formula RₓT_{y}M_{z}. The design of the electronic circuitry will depend on the use for the device. Once the use is determined, the skilled person will be able to develop the appropriate electronic circuitry.

The electronic circuitry may be electrically connected to the thermoelectric device using conventional techniques such as by soldering and/or by using conducting adhesive.

In a typical thermoelectric device, conductive metal is applied to the opposing surfaces of the legs, corresponding to the hot side and the cold side. The metal may be applied by metal coating technique such as evaporation/condensation and the like. Adjacent N/P pairs may be connected in parallel with the conductive metal. In the alternative, the conductive metal may be soldered or adhered to the metal with a conductive material. In many cases, an insulating substrate such as a ceramic or the like covers the metal contacts. Wiring may be applied to the metal contacts by wire bonding, soldering, or the like.

The thermoelectric apparatus and device may be used at many different temperature ranges depending on the RₓT_{y}M_{z} selected, but it is particularly advantageous for use at temperatures of 100 K or below, 90 K or below, 80 K or below, 70 K or below, 60 K or below, 50 K or below, 40 K or below, 30 K or below, or 20 K or below. Such temperatures are known as cryogenic temperatures. This is because PF and ZT are very favorable at cryogenic temperatures. In a particular example the thermoelectric apparatus and device is used within an ambient temperature range of about 100 K to about 2 K, about 80 K to about 2 K, about 50 K to about 2 K, or about 35 K to about 2K.

### EXAMPLES

This section describes details of particular examples of the thermoelectric materials and characterization of their physical properties. These examples are being provided to illustrate certain aspects of the materials and their properties. The scope of possible embodiments of the devices, methods, and materials described here is not limited to the teachings in this section.

### Example 1

### Synthesis of Exemplary Thermoelectric Materials

High-purity single crystals of YbT₂Zn₂₀ (T=Co, Rh, Ir) were synthesized by a molten flux growth method. Yb chunks (99.9%, Ames Labs), Co ingots (99.99%, Alfa Aesar), Rh ingots (99.99%, Alfa Aesar), Ir ingots (99.99%, Alfa Aesar), and Zn shots (99.999%, Alfa Aesar) in the atomic ratio of Yb:T:Zn (T=Co, Rh, Ir)=1:2:60 were loaded into 2 mL alumina crucibles and sealed under vacuum in quartz tubes. The quartz tubes were then heated to 1050° C. at a rate of 50° C./hour, held at 1050° C. for 24 hours, and then cooled to 700° C. at a rate of 4° C./hour. At this temperature, the remaining flux was separated from the crystals by centrifuging. Multi millimeter size single crystals were obtained.

### Example 2

### Structural Characterization

The YbT₂Zn₂₀ single crystals were characterized structurally by single-crystal X-ray diffraction (XRD) using an Oxford-Diffraction Xcalibur2 CCD system with graphite monochromated Mo Kα radiation. Data were collected using ω scans with 1° frame widths to a resolution of 0.4 Å, equivalent to 2θ≈125°. Reflections were recorded, indexed, and corrected for absorption using the Oxford-Diffraction CRYSALISPRO software, and subsequent structure determination and refinement were carried out using the single-crystal X-ray structure refinement and analysis software package CRYSTALS, with a SUPERFLIP phasing algorithm on F². The data quality allowed for an unconstrained full matrix refinement against F² with anisotropic thermal displacement parameters for all atoms. The crystallographic information files (CIFs) have been deposited with the Inorganic Crystal Structure Database (ICSD CSD-434009, CSD-434010, and CSD-434011 for YbCo₂Zn₂₀, YbRh₂Zn₂₀, and YbIr₂Zn₂₀, respectively). Electron dispersive spectroscopy (EDS) analyses corroborated the stoichiometries obtained from the refinement results.

The cage dimensions of YbT₂Zn₂₀, defined as the longest distance between the two vertices in the cage frame, are about 6 Å. The X-ray diffraction measurements reveal large atomic displacement parameters of the Yb ions.

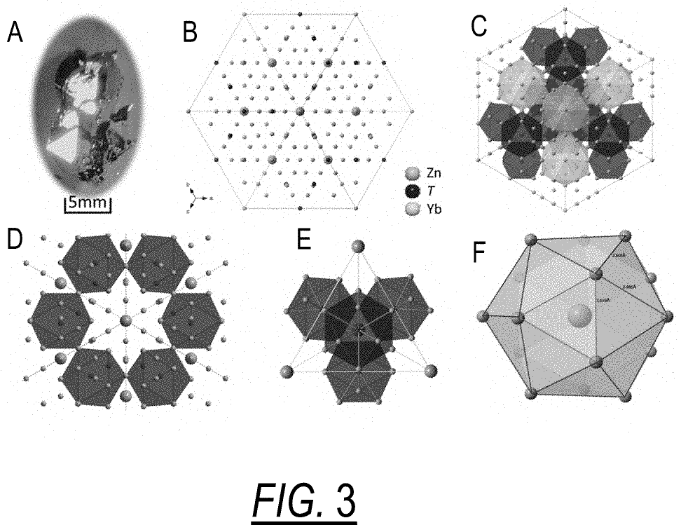

YbT₂Zn₂₀ (T=Co, Rh, Ir) crystallized in space group Fd-3m (#227) with Z=8. Using the molten metal flux growth technique, large single crystals of YbT₂Zn₂₀ in several millimeters size were obtained. For example, FIG. 3A shows the as-synthesized YbCo₂Zn₂₀ with the triangle face corresponding to the (111) crystallographic plane, indicating a [111] directional growth preference. FIG. 3B shows the unit cell viewed along the [111] direction, suggesting a Kagome lattice formed by the Yb and the transition metal atoms. The structure shows that each Yb atom is surrounded by 16 Zn atoms and T by 12 Zn atoms, thus forming two types of polyhedrons (Frank-Kasper polyhedron and icosahedron, respectively) in the cage-like structure (FIG. 3C).

There is no direct bonding between any Yb nor T atoms. The coordination between the Yb atoms and the T-Zn cages are shown in FIG. 3D and FIG. 3E. For the Frank-Kasper polyhedron (FIG. 3F), the framework is formed by 4 nearest neighbors (16c) and 12 next nearest neighbors (96g) of Zn atoms with Yb at the center. When rare-earth atoms are inside a cage-like structure, very often these heavy atoms are not well bonded and would tend to “rattle”, creating a soft lattice mode affecting the phonon transport.

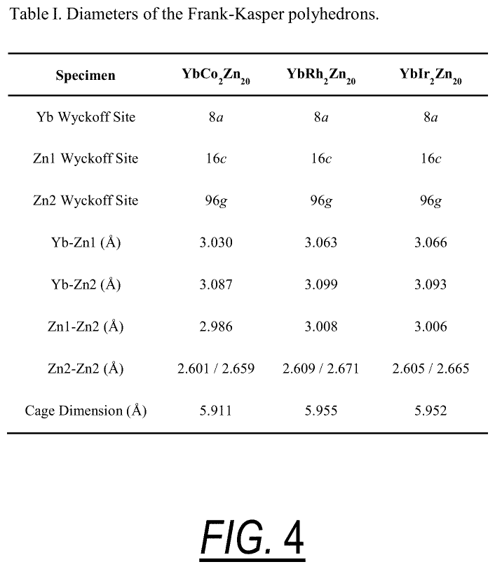

The cage dimension is the longest distance between the Zn atoms in the cage framework and list the diameters of the Frank-Kasper polyhedra in Table 1 (FIG. 4). The cage dimension changes slightly with the T atoms and the largest value was observed in YbRh₂Zn₂₀, presumably due to the larger covalent radius of Rh as compared to Co and Ir. Overall the cage dimension of YbT₂Zn₂₀ has a value that is comparable to that of the Yb-filled skutterudite Yb_{0.1}CoSb₃ and the skutterudite derivative Yb_{0.14}Co₄Ge₆Se₆. The “rattling” feature of Yb atoms was observed and will be discussed in the light of understanding the phonon transport in these materials.

### Example 3

### Thermoelectric Properties Characterization

The temperature dependence of the thermopower (S), electrical resistivity (ρ), heat capacity (Cₚ), thermal conductivity (κ), and the thermoelectric figure of merit ZT=S²T/ρκ, where T is the absolute temperature for this family of materials, are now described.

The single crystals of YbT₂Zn₂₀ were aligned on a CAD-4 diffractometer along their [100]-axis before being cut into a rectangular slab of 2 mm×1 mm×0.5 mm dimensions for temperature dependent four-probe ρ, S (gradient sweep method), and steady-state κ measurements in the temperature range from 12 to 300 K. The crystals were mounted such that the current and the thermal gradient were along the [100] direction. All the surfaces were polished using 3 μm grid diamond polishing paper to reduce surface radiation losses during the measurements. The measurements were carried out in a custom radiation-shielded vacuum probe with uncertainties of 4, 6, and 8% for ρ, S, and κ measurements, respectively. Electrical contacts to the specimens were made using silver epoxy and thermal contacts were made using stycast epoxy.

Temperature dependent Seebeck coefficient (S) measurements (gradient sweep method), four-probe resistivity (ρ) measurements, and steady-state thermal conductivity (κ) measurements from 12 to 300 K were applied to single crystals of YbT₂Zn₂₀. The single crystals were carefully aligned before mounting so that both the thermal gradient and the electrical current are along the [100] crystallographic direction.

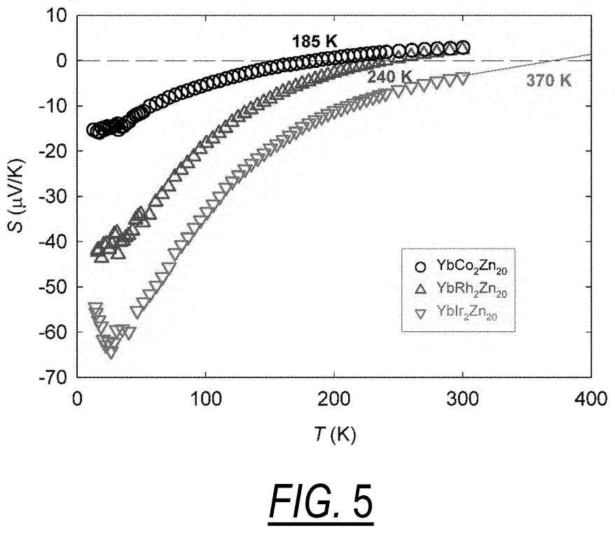

FIG. 5 shows S as a function of temperature. Peaks in S were observed at low temperatures due to phonon drag. Above the peak temperature, the absolute value of S decreases with increasing temperature, eventually crossing over zero and changing the sign from negative to positive at 185 K and 240 K for YbCo₂Zn₂₀ and YbRh₂Zn₂₀, respectively, indicating the majority charge carrier has changed from holes to electrons. The S of YbIr₂Zn₂₀ does not reach zero up to 300K. The trend of the higher temperature data was followed to estimate a cross-over temperature of 370 K.

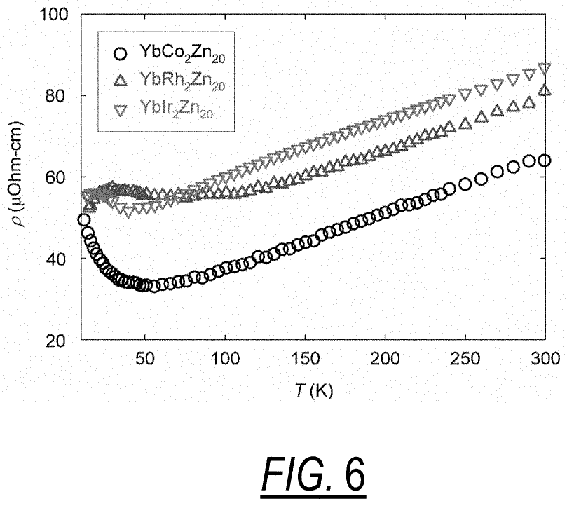

FIG. 6 shows the temperature dependent ρ(T) of three specimens: ρ decreases with increasing temperature at lower temperatures and then increases, indicating a transition from semi-conducting type to metallic. The solid lines in FIG. 6 are fits using ρ=ρ₀ exp(Eₐ/k_{B}T) where Eₐ represents the activation energy. From the fits, an activation energy of 10 meV around room temperature for all three specimens was estimated. The S values at low temperatures as well as the relatively low p contribute to peak values in the power factor (PF=S²/ρ) of 7 μW/cm-K², 35 μW/cm-K², and 74 μW/cm-K² for YbCo₂Zn₂₀, YbRh₂Zn₂₀ and YbIr₂Zn₂₀, respectively.

Furthermore, the specific material property requirements for good thermoelectric materials can be quantified by the figure of merit ZT=S²T/ρκ, where T is the absolute temperature and κ is the thermal conductivity (κ=κ_{L}+κ_{E} where κ_{L} and κ_{E} are the lattice and electronic contributions, respectively).

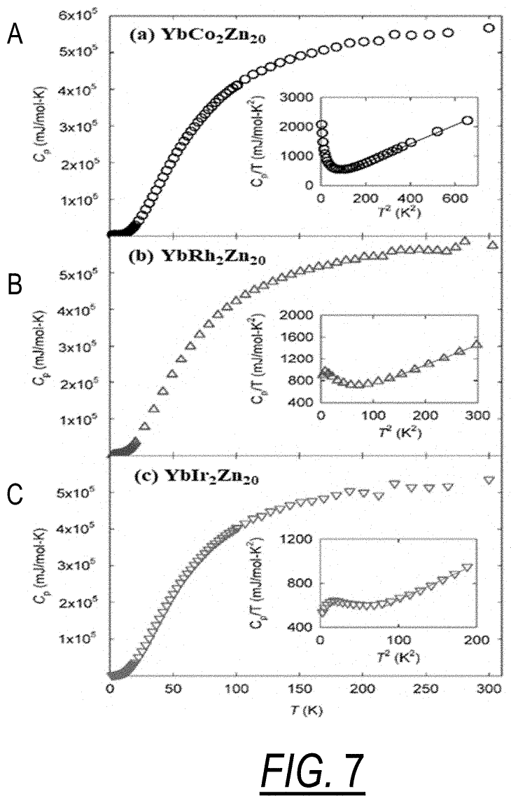

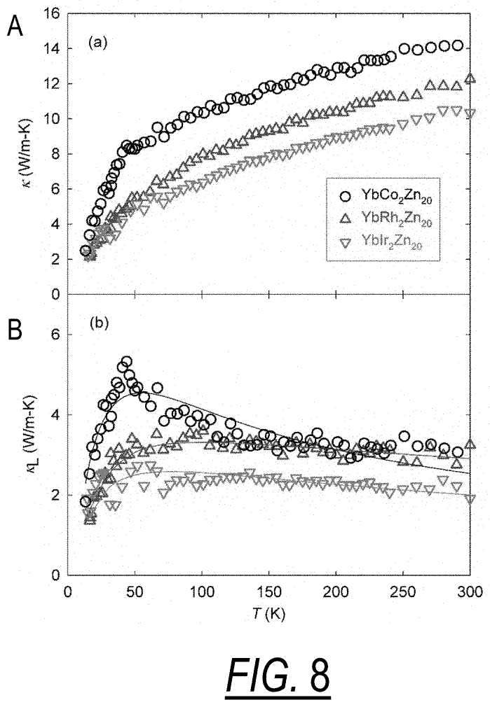

The heat capacity (Cₚ) of YbT₂Zn₂₀ (FIG. 7) was measured and the θ_{D} estimated from the T³ dependence region, to be 239 K, 228 K, and 224 K for YbCo₂Zn₂₀, YbRh₂Zn₂₀, and YbIr₂Zn₂₀, respectively. FIG. 8A shows the measured κ from 12 K to 300K. Applying the Wiedemann-Franz law where κ_{E}=L₀σT (L₀ is the Lorentz number), we obtained the κ_{L} as a function of temperature from κ−κ_{E} (FIG. 8B). Due to the low ρ values of YbT₂Zn₂₀, κ is dominated by κ_{E} among the entire measured temperature range. The overall lower ρ of YbCo₂Zn₂₀, compared with that of the other two systems, contributes to a higher κ_{E}, and therefore a higher κ. After subtracting κ_{E}, however, the differences between the κ_{L} of all three systems are much reduced, as expected from compounds belonging to the same family. The solid lines in FIG. 8B are theoretical fits to the data using the Debye approximation

$${κ}_{L} = \frac{{k}_{B}}{2 {π}^{2} υ} {( \frac{{k}_{B} T}{υ} )}^{3} {\int }_{0}^{{θ}_{D} / T} \frac{{x}^{4} {e}^{x}}{{{τ}_{C}^{- 1} ( {e}^{x} - 1 )}^{2}} dx \qquad Eq . ( 1 )$$

where x=ℏω/k_{B}T is dimensionless, ω is the phonon frequency, ν is the speed of sound, and τ_{C} is the phonon scattering relaxation time. τ_{C}⁻¹ can be further written as

$${τ}_{C}^{- 1} = \frac{υ}{L} + A {ω}^{4} + B {ω}^{2} T exp ( - \frac{{θ}_{D}}{3 T} ) + \frac{C {ω}^{2}}{{( {ω}_{0}^{2} - {ω}^{2} )}^{2}} \qquad Eq . ( 2 )$$

where L is the grain size, ω₀ is the resonance frequency, and the coefficients A, B, and C are fit parameters. The terms in Eq. (2) represent grain boundary phonon scattering, point defect phonon scattering, Umklapp scattering, and resonance scattering, respectively.

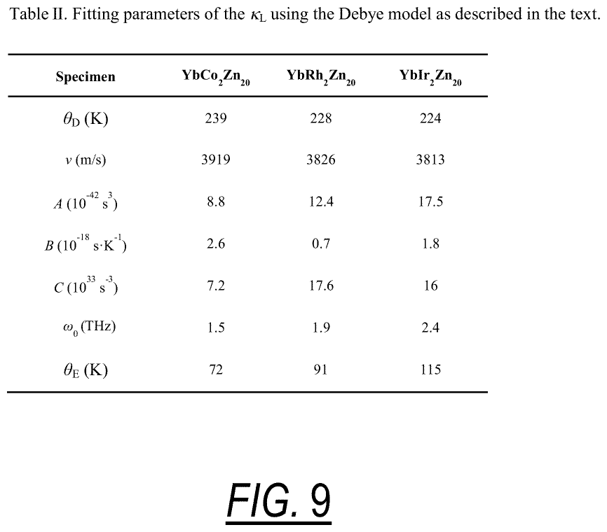

The ν values were calculated from an elastic constant reported in the literature. The fit parameters were defined using a minimization of best sequence fit functions as compared to the experimental data and are listed in Table II (FIG. 9) together with the other related physical parameters. Excluding the transition elements, in each formula unit the average mass of each atom is about 70 g/mol. As the transition element changes from Co to Rh and then Ir, the mass difference between the T and the average atomic mass of the unit cell increases. Therefore, it creates enhanced mass fluctuation scattering between the T and the rest of the atoms in the unit cell, as indicated by the increased point defect phonon scattering parameter A.

In order to quantitively investigate the effect of the transition metals on B, information about the Grüneisen parameters are required. ω₀ represents the “rattling” frequency of Yb atoms due to the dynamic disorder resonance. From fitting the κ_{L} using the Debye model all three specimens obtained similar values of ω₀. This is as expected since all three specimens have a similar cage size. The ω₀ values of YbT₂Zn₂₀ are similar to that of Yb_{0.19}Co₄Sb₁₂₋ₓSnₓ (x=0, 0.05, and 0.2) due to size similarity of the cages. Based on the ω₀, an Einstein temperature (θ_{E}=hω₀/k_{B}) was estimated to be 72 K, 91 K, and 115 K for YbCo₂Zn₂₀, YbRh₂Zn₂₀, and YbIr₂Zn₂₀, respectively.

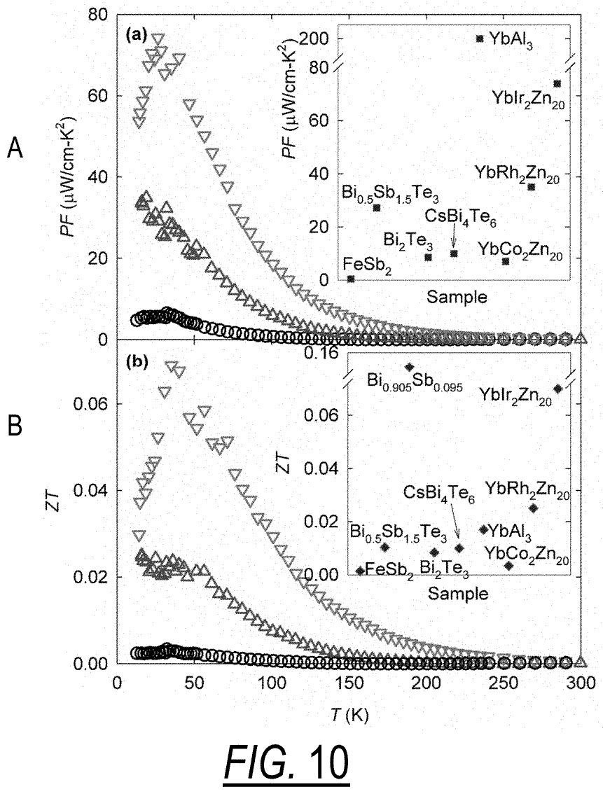

The large PF values of YbT₂Zn₂₀ compounds (FIG. 10A) are accompanied by a remarkably large value of ZT=0.07 at 35 K for YbIr₂Zn₂₀ (FIG. 10B, which, to our knowledge, is the highest ZT that has ever been reported in this temperature range. For comparison, the insets of FIG. 10A and b show PF and ZT at 35 K for several well-known thermoelectric materials: FeSb₂, Bi_{0.5}Sb_{1.5}Te₃ (thermoelectric material from Marlow industry), Bi₂Te₃ (thermoelectric material standard from National Institute of Science and Technology), and CsBi₄Te₆. The ZT of YbIr₂Zn₂₀ is an order of magnitude higher than the others.

Magnetic, transport, and thermal measurements of the YbT₂Zn₂₀ materials suggest a heavy fermion ground state that arises from Kondo coherence from hybridization between the localized Yb f-electron states and the delocalized conduction electron states. This leads to both a low electrical resistivity and a peak in the thermopower which combine to yield an enhanced PF at low temperatures. Together with the reasonably low K as a result of the rattling motion of the Yb ions, this accounts for the large ZT.

There are several strategies to tune the ZT in the temperature region where the power factor has its peak value. From the “phonon-glass” point of view, κ will need to be further reduced. This can be achieved by modifying the Yb “rattling”. Moreover, since grain boundary phonon scattering dominates κ_{L} at the very lowest temperatures, nanostructuring the materials may provide an alternative way to reduce κ_{L}, therefore tuning the ZT values, due to the effect of significant interface scatterings at the grain boundaries.

The electrical properties may be tuned by composition modifications to enhance the PF of these materials. Due to the Kondo lattice hybridization, the ρ(T) of the 1-2-20 materials decreases with decreasing temperature below the coherent temperatures.

The sharp change of the density of states near the Fermi level, contributed by the elements with unstable valences, results in a large S. By substituting Yb with other rare earth elements, Ce, Tm or Eu for example, changes in both the peak values of the PF as well as the temperature region for the PF peak can be achieved. Such tunability can be investigated to alter the temperature region in which these 1-2-20 materials can be applied for efficient thermoelectric energy conversion applications. Moreover, since both n-type and p-type thermoelectric materials are needed to construct thermoelectric modules, replacing Yb with Ce may be useful because Ce and Yb are electron/hole analogues.

The Seebeck coefficient S exhibits a peak that is maximized for T=Ir near 35 K at an enhanced value of −65 μV/K. At the same time, the lattice thermal conductivity is reduced by the rattling behavior of the Yb with values in the range of 2-5 W/m-K for all three compounds. Conveniently, it is minimized for the T=Ir analogue. The low temperature ρ varies depending on the coherence temperature of the materials, but is similar, with values of 30-60 mΩ-cm for all three compounds.

ZT was calculated from these quantities and was found to be remarkably large for YbIr₂Zn₂₀, reaching a value of ZT=0.07 at T=35 K. At this temperature the ZT value is nearly an order of magnitude larger than that of the most competitive and well-known thermoelectric materials for thermoelectric cooling applications: particularly Bi₂₋ₓSbₓTe₃ and chemical analogues like CsBi₄Te₆.

### Example 4

### Thermoelectric Properties Characterization of Yb_{0.75}Ce_{0.25}Co₂Zn₂₀

In this example, R=Yb_{0.75} and Ce_{0.25}. This material was prepared using the molten flux growth methods with a stoichiometric ratio of Yb and Ce.

Yb_{0.75}Ce_{0.25}Co₂Zn₂₀ was synthesized by a molten flux growth method. Yb chunks (99.9%, Ames Labs), Ce rod (99.8%, Alfa Aesar), Co ingots (99.99%, Alfa Aesar), and Zn shots (99.999%, Alfa Aesar) in the atomic ratio of Yb:Ce:Co:Zn=0.75:0.25:2:60 were loaded into 2 mL alumina crucibles and sealed under vacuum in quartz tubes. The quartz tubes were then heated to 1050° C. at a rate of 50° C./hour, held at 1050° C. for 24 hours, and then cooled to 700° C. at a rate of 4° C./hour. At this temperature, the remaining flux was separated from the crystals by centrifuging. Multi millimeter size single crystals were obtained.

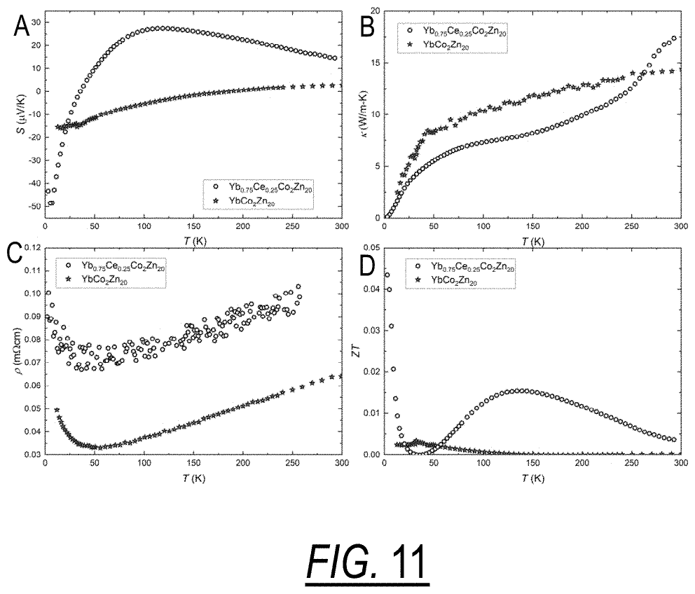

The data in FIG. 11 show that changing using mixed metals for R increases the maximum value of ZT by an order of magnitude.

The apparatus, devices, materials and methods are not limited to the details described in connection with the example embodiments. There are numerous variations and modification of the compositions and methods that may be made without departing from the scope of what is claimed.

That which is claimed is:

1. An apparatus comprising a thermoelectric device including a first thermoelectric material having the formula RₓT_{y}M_{z} where R is at least one rare earth metal, Ba, or Bi and 0≤x≤1; T is at least one transition metal and 0<y≤2; and M is at least one member of the group Al, Zn, Ga, Cd, and In and 0<z≤20.

2. The apparatus of claim 1, wherein the device is selected from a thermoelectric refrigerator, a thermoelectric heater, and a thermoelectric electrical generator.

3. The apparatus of claim 1, wherein the first thermoelectric material is an n-type semiconductor and the device further includes a second thermoelectric material that is a p-type semiconductor.

4. The apparatus of claim 1, wherein R is selected from Bi, Ba, Y, La, Ce, Pr, Nd, Pm, Sm, Eu, Gd, Tb, Dy, Ho, Er, Tm, Yb, Lu, Th, U, Np, and Pu.

5. The apparatus of claim 1, wherein R is Yb and Ce.

6. The apparatus of claim 1, wherein T is at least one member of the group Ag, Ti, V, Cr, Mn, Fe, Co, Ni, Cu, Mo, Ru, Rh, Pd, W, Os, Ir, and Pt.

7. The apparatus of claim 1, wherein T includes at least one member of the group Co, Rh, and Ir.

8. The apparatus of claim 1, wherein M includes Zn.

9. The apparatus of claim 1, wherein:
R is Yb and Ce;
T includes at least one of Co, Rh, and Ir; and
M includes Zn.

10. The apparatus of claim 1, wherein the first thermoelectric material is selected from Yb_{0.75}Ce_{0.25}Co₂Zn₂₀, Yb_{0.75}Ce_{0.25}Rh₂Zn₂₀, and Yb_{0.75}Ce_{0.25}Ir₂Zn₂₀.

11. The apparatus of claim 1, wherein the first thermoelectric material is in electrical contact with electronic circuitry.

12. A method of making a thermoelectric device, the method comprising connecting electronic circuitry to a thermoelectric device including a first thermoelectric material having the formula RₓT_{y}M_{z} where R is at least one rare earth metal, Ba, or Bi and 0≤x≤1; T is at least one transition metal and 0<y≤2; and M is at least one member of the group Al, Zn, Ga, Cd, and In and 0<z≤20.

13. The method of claim 12, wherein the device is selected from a thermoelectric refrigerator, a thermoelectric heater, and a thermoelectric electrical generator.

14. The method of claim 12, wherein the first thermoelectric material is an n-type semiconductor and the device further includes a second thermoelectric material that is a p-type semiconductor.

15. The method of claim 12, wherein R is selected from Bi, Ba, Y, La, Ce, Pr, Nd, Pm, Sm, Eu, Gd, Tb, Dy, Ho, Er, Tm, Yb, Lu, Th, U, Np, and Pu.

16. The method of claim 12, wherein R is Yb and Ce.

17. The method of claim 12, wherein T is at least one member of the group Ag, Ti, V, Cr, Mn, Fe, Co, Ni, Cu, Mo, Ru, Rh, Pd, W, Os, Ir, and Pt.

18. The method of claim 12, wherein T includes at least one member of the group Co, Rh, and Ir.

19. The method of claim 12, wherein M includes Zn.

20. The method of claim 12, wherein:
R includes Yb and Ce;
T includes at least one of Co, Rh, and Ir; and
M includes Zn.

21. The method of claim 12, wherein the first thermoelectric material is selected from Yb_{0.75}Ce_{0.25}Co₂Zn₂₀, Yb_{0.75}Ce_{0.25}Rh₂Zn₂₀, Yb_{0.75}Ce_{0.25}Ir₂Zn₂₀.
